(19) United States
(12) Patent Application Publication
(10) Pub. No.: US 2002/0166500 A1
(43) Pub. Date: Nov. 14, 2002

(54) Calcium fluoride crystal and method and apparatus for producing the same

(76) Inventors: Nobukazu Yogo, Abiko-shi (JP); Tetsuo Kuwabara, Ibaraki-ken (JP)

Correspondence Address: MORGAN & FINNEGAN, L.L.P., 345 PARK AVENUE, NEW YORK, NY, 10154, US

(21) Appl. No.: 10/085,500

(22) Filed: Feb. 26, 2002

(30) Foreign Application Priority Data
Feb. 27, 2001 (JP) 051935/2001(PAT.)
Jan. 30, 2002 (JP) 022480/2002(PAT.)

(51) Int. Cl. C30B 13/00; C30B 21/04; C30B 28/08

(52) U.S. Cl. 117/43; 117/37

(57) ABSTRACT

Disclosed is a method of producing fluoride crystal, wherein the method includes a dehydrating step for dehydrating a raw material of fluoride by heating a crucible being adapted to accommodate a raw material of fluoride therein and having an exhaust mechanism for exhausting an inside gas of the crucible, and a exhausting step for exhausting, in the dehydrating step, an inside gas of the crucible by use of the exhaust mechanism.

### FIELD OF THE INVENTION AND RELATED ART

This invention relates a producing method and apparatus for producing a fluoride crystal suitably usable in various optical elements, lenses, windows or prisms, for example, which are to be used with light of a predetermined wavelength selected out of a wide wavelength range, ranging from vacuum ultraviolet region to deep ultraviolet region. More particularly, the invention concerns a method and apparatus for producing a fluorite crystal suitably usable as an optical component (or optical element) for excimer lasers.

Excimer lasers have attracted attentions because they are a sole high-power laser which can oscillate in an ultraviolet region, and the applicability of them in electronic industry, chemical industry, and energy industry, have been expected. More specifically, they are used in processes or chemical reactions for metal, resin, glass, ceramics and semiconductors, for example. Among excimer lasers, ArF laser and F2 laser provides light of wavelength region, called a vacuum ultraviolet region, of wavelengths such as 193 nm and 158 nm, respectively. Optical systems to be used therewith must have a high transmissivity to light of such wavelength region. Examples are crystals such as calcium fluoride (fluorite), barium fluoride, and magnesium fluoride.

Now, taking calcium fluoride as an example, conventional methods of producing fluoride crystal will be explained.

For a crystal to be used with the infrared region to the visible region, naturally yielded inexpensive fluorite ore is used as a raw material. For a crystal to be used in the ultraviolet or vacuum ultraviolet region, if natural fluorite is used, because of a large content of impurities, absorption will occur in the ultraviolet or vacuum ultraviolet region. For this reason, a high-purity powder raw material produced chemically synthetically is used.

In order to increase the bulk density of this raw material and to remove impurities in the raw material, a process for fusing and refining the raw material is necessary. In such refining process, in order to remove oxides produced by reaction of the raw material with moisture or the like or to remove impurities in the raw material, a scavenger which is fluoride of metal must be added to the raw material. For example, in a case where the fluoride crystal is calcium fluoride and the scavenger is solid ZnF2, CaO which is produced by reaction of the raw material with moisture reacts with ZnF2, and it changes to CaF2. Also, the scavenger changes to ZnO, and it evaporates as the raw material is fused.

If a block of fluoride crystal produced by the refining process is used as a secondary raw material to produce a final crystal, it is expected that monocrystal of fluoride having a very superior optical performance such as transmission characteristic, for example, can be produced. To this end, after a block of fluoride crystal produced by the refining process is fused, a growing crucible is pulled down at a speed of about 0.1-5 mm/H, by which crystal growth occurs gradually from the bottom of the crucible such that calcium fluoride monocrystal is produced (monocrystal growing process).

Even in this monocrystal growing process, moisture is adhered to the surface of the fluoride crystal produced in the refining process, and it reacts with the crystal to produce CaO. For this reason, a scavenger (e.g., AnF2) is added, like the refining process. The function of the scavenger is like that in the refining process, and CaO which is produced by reaction of the raw material with moisture reacts with ZnF2, and it changes to CaF2. Also, the scavenger changes to ZnO, and it evaporates as the raw material is fused.

In relation to the production processes, Japanese Laid-Open Patent Application, Laid-Open No. 2000-191322 discloses that, during the heating process for fusing the fluoride raw material with a scavenger added thereto, emission of gases in a room for accommodating the fluoride raw material to the outside thereof is facilitated to thereby prevent products within the room such as carbon monoxide or the like or vaporized scavenger from being mixed into the raw material.

### SUMMARY OF THE INVENTION

It has been found that there is a possibility that, only by facilitating emission of gases inside the room in the heating process as disclosed in the aforementioned patent document, impurities in the fluoride can not be removed sufficiently.

Further, there is a possibility that, only by changing the ambience inside the room in accordance with the room temperature, since the rate of moisture contained in the air, for example, differs with seasons, fluoride of a desired characteristic can not be produced constantly.

It is accordingly an object of the present invention to provide a fluoride crystal producing method and apparatus for producing fluoride crystal having a transmissivity characteristic which is less deteriorated even when it is irradiated by light of short wavelength and large power frequently, for a long time.

It is another object of the present invention to provide a fluoride crystal producing method and apparatus by which evaporation of fluoride raw material can be suppressed such that the yield of fluoride crystal can be improved, that the production cost can be lowered even where the unit price of the raw material is expensive, and that emission of industrial wastes can be reduced.

It is a further object of the present invention to provide a fluoride crystal producing method and apparatus by which a stable dehydrated state can be achieved even if the moisture content adhered previously to the fluoride raw material or a furnace changes with seasons or due to differences in production lot of the raw material, such that the quality product rate of the refined product or the final crystal can be improved, and that the versatility is expanded.

In order to achieve these objects, the present invention provides a method of producing fluoride crystal which method can be either a method of refining fluoride or a method of producing fluoride monocrystal (monocrystal growing method).

In accordance with an aspect of the present invention, there is provided a method of producing fluoride crystal, comprising the steps of: dehydrating a raw material of fluoride by heating a crucible being adapted to accommodate a raw material of fluoride therein and having an exhaust mechanism for exhausting an inside gas of the crucible; and exhausting, in said dehydrating step, an inside gas of the crucible by use of the exhaust mechanism. With this method, during the dehydration process, gases can be exhausted while a lid is held opened, such that the dehydration efficiency is improved.

The crucible may further be adapted to accommodate a scavenger therein, and the crystal producing method may further comprise a step of causing reaction of the scavenger to remove impurities contained in the fluoride raw material, and a step of sealingly closing the crucible without performing the gas exhaust from the crucible by the exhaust mechanism, in said reaction step. With this method, by sealingly closing the crucible, evaporation and resultant decrease of the scavenger can be prevented. Also, by the closure, the reaction itself is accelerated.

The method may further comprise a step of removing a product produced as a result of reaction of the scavenger, and a step of exhausting an inside gas of the crucible by use of the exhaust mechanism in said removing step. With this method, since gases are exhausted while a lid is kept opened, the efficiency of removing vaporized products is improved, such that harmful moisture and harmful scavenge reactant (product of reaction between the fluoride raw material and the scavenger) adhered to the raw material or the furnace can be discharged outwardly of the crucible.

The method may further comprise a step of fusing and solidifying the fluoride raw material, or alternatively, a step of crystal-growing by gradually pulling down a crucible after the fluoride raw material is fused. The method may further comprise a step of sealingly closing the crucible in said fusing, solidifying or crystal-growing step. With this method, by closure of the crucible, evaporation and resultant decrease of the fluoride crystal component in the fusing and solidifying step can be prevented.

In another aspect of the present invention, the lid of the crucible can be demounted from a mechanism for opening and closing the lid, as required. With this structure, in the process of crystal growing with the crucible pulled down, the lid of the crucible can be separated beforehand from the lid opening/closing mechanism, such that the crucible can be pulled down through a relatively long distance with the lid thereof can be kept opened.

In accordance with a further aspect of the present invention, there is provided a method of producing fluoride crystal, comprising the steps of: detecting a vacuum level of a process chamber for accommodating therein a crucible being adapted to accommodate a raw material of fluoride therein and having an exhaust mechanism for exhausting an inside gas of the crucible; and controlling the gas exhaust through the exhaust mechanism, on the basis of the vacuum level detected. With this method, since the opening and closing of the lid can be controlled on the basis of the vacuum level, the lid can be opened and closed in accordance with the progress of the manufacturing processes, that is, the dehydration state, for example.

In accordance with a yet further aspect of the present invention, there is provided a crystal producing apparatus, comprising: a process chamber for producing fluoride crystal; a pressure detecting unit for detecting a pressure of said process chamber; a crucible accommodated in said process chamber and being adapted to accommodate a raw material of fluoride therein, said crucible having an exhaust mechanism for exhausting an inside gas of said crucible; and a control unit for controlling the gas exhaust through said exhaust mechanism, on the basis of the pressure of said process chamber detected by said pressure detecting unit. With this structure, since the control unit controls the opening/closing of the lid of the crucible on the basis of the pressure inside the process chamber, the lid can be opened and closed in accordance with the progress of the producing processes.

In accordance with a still further aspect of the present invention, there is provided an optical element which is produced by use of a crystal of fluoride produced by a manufacturing apparatus as recited above.

The optical element may be one of a lens, a diffraction grating, an optical film and a composite of them, that is, for example, a lens, a multiple lens, a lens array, a lenticular lens, a fly's eye lens, an aspherical lens, a diffraction grating, a binary optics element, and a composite of them. In addition to a single element of lens or the like, the optical element may be a photosensor for focus control, for example.

In accordance with a still further aspect of the present invention, there is provided an exposure apparatus in which one of ultraviolet light, deep ultraviolet light and vacuum ultraviolet light is used as exposure light, and wherein the exposure light is projected on a workpiece through an optical system including an optical element as recited above to expose the workpiece with the exposure light. Such exposure apparatus has advantages like the optical element described above.

In accordance with a further aspect of the present invention, there is provided a device manufacturing method, comprising the steps of: exposing a workpiece by use of an exposure apparatus as recited above; and performing a predetermined process to the exposed workpiece. The scope of the present invention related to the device manufacturing method described above extends, like that of the exposure apparatus, to a device itself which may be an intermediate product or a final product. The device may be a semiconductor chip such as LSI or VLSI, or it may be CCD, LCD, magnetic sensor or a thin film magnetic head, for example.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1 is a flow chart for explaining producing processes according to the present invention, from a process for fluoride raw material to a shaping process for forming fluoride crystal optical element.

FIG. 2 is a flow chart for explaining a refining process in an embodiment of the present invention.

FIG. 3 is a flow chart for explaining a refining process in another embodiment of the present invention.

FIG. 4 is a flow chart for explaining a monocrystal growing process in an embodiment of the present invention.

FIG. 5 is a flow chart for explaining a monocrystal growing process in another embodiment of the present invention.

FIG. 6 is a schematic view of a section of a refining system.

FIG. 7 is a sectional view of a section of a crystal producing apparatus.

FIG. 8 is a perspective view of a lid for a crucible.

FIG. 9 is a graph for explaining spectral characteristics of calcium fluoride crystals (refined products) produced under various conditions.

FIG. 10 is a schematic and sectional view of an exposure apparatus according to the present invention.

FIG. 11 is a flow chart for explaining device manufacturing processes, including an exposure process according to the present invention.

FIG. 12 is a flow chart for explaining details of step 104 in FIG. 11.

### DESCRIPTION OF THE PREFERRED EMBODIMENTS

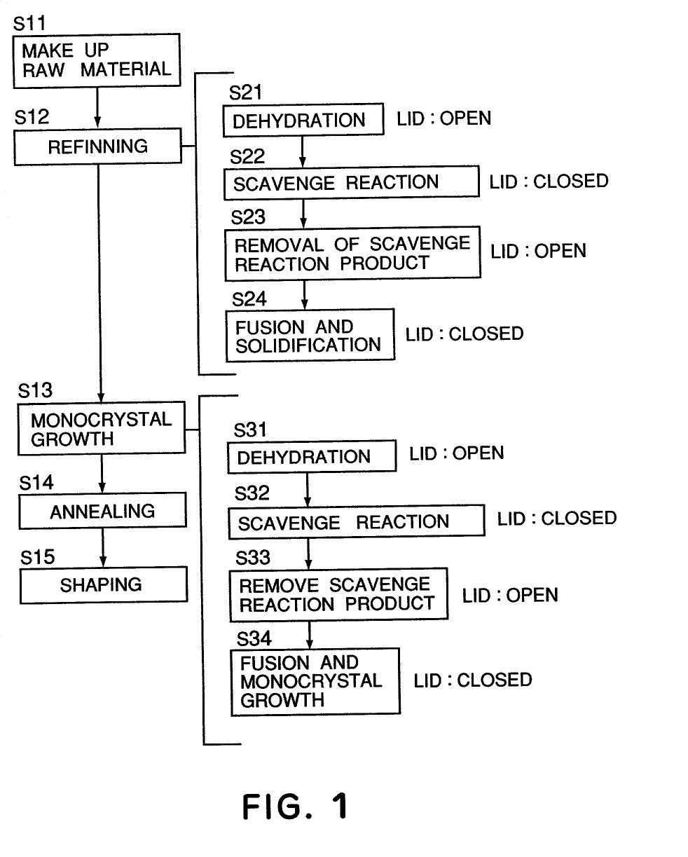

FIG. 1 is a flow chart of a fluoride refining method and a fluoride crystal producing method, in accordance with an embodiment of the present invention.

[Raw Material Makeup Step S11]

A scavenger is added to a fluoride raw material, and they are mixed sufficiently. The amount of scavenger addition should be not less than 0.02 mol % of the raw material and not greater than 2 mol %. The raw material for fluoride is calcium fluoride, barium fluoride, magnesium fluoride, or the like. The fluoride to be used as solid scavenger should desirably be zinc fluoride, manganese fluoride, lead fluoride, bismuth fluoride, sodium fluoride, lithium fluoride and the like.

Here, zinc fluoride scavenger, for example, functions in accordance with formula 2 below to change calcium oxide (formula 1) produced due to the presence of moisture into calcium fluoride. The produced zinc oxide is reduced in accordance with formula 3, and carbon monoxide gas (or carbonic acid gas) is produced. Thus, oxidation of calcium fluoride is prevented. This is what is known as scavenge reaction (impurity removing reaction by scavenger).

CaF2+H2O→CaO+2HF (Formula 1)

CaO+ZnF2→CaF2+ZnO (Formula 2)

ZnO+C→Zn+CO(or CO2) (Formula 3)

[Refining Step S12]

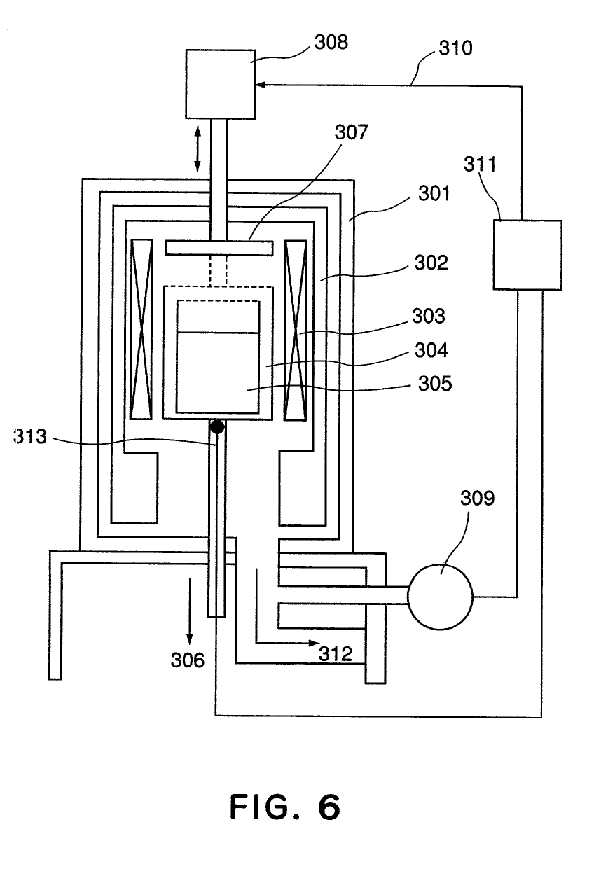

The fluoride raw material in which a scavenger has been added and mixed is put into a crucible of a refining furnace shown in FIG. 6. In FIG. 6, denoted at 301 is a chamber for the refining furnace, and it is connected to a vacuum exhaust system 312. Denoted at 302 is a heat insulating material, and denoted at 303 is a heater. Denoted at 304 is a crucible which functions as a room for accommodating the raw material. Denoted at 305 is the fluoride raw material. The element 306 is connected to a mechanism for moving the crucible upwardly and downwardly. The crucible is provided with a lid 307. Also, there is a mechanism 308 for moving the lid upwardly and downwardly at the top of the refining furnace, and by this mechanism, the lid can be opened and closed. In FIG. 6, the state in which the lid is opened is illustrated by solid lines, while the state in which the lid is closed is illustrated by broken lines. Denoted at 309 is a vacuum gauge for measuring the vacuum level inside the chamber. The measured vacuum level is signaled to a control unit 311. On the basis of the measurement result, the control unit 311 controls the lid moving mechanism 308 for opening and closing the lid 307 of a crucible 304, through a signal line 310. The temperature of the crucible 304 is measured by means of a thermocouple 313 and the result is transmitted to the control unit 311.

[Dehydrating Step S21]

In this embodiment, initially, the control unit 311 controls the mechanism 308 so as to open the lid 307 of the crucible 304. Subsequently, the control unit 311 controls the vacuum exhaust system 312 to start gas exhaust. After the vacuum gauge 309 detects that a predetermined vacuum level is reached, the heater 303 is energized to heat the crucible 304. Since the moisture attracted to the fluoride raw material or the crucible 304 is removed by dehydration, from about 100-300° C., the rate of heating up to 300° C. or less may be made slower or, alternatively, an appropriate temperature between 100-300° C. may be held for a long time period. In this process, the stage whereat the dehydration has progressed largely is monitored by the vacuum gauge 309. The vacuum gauge 309 monitors whether the vacuum level is stable or not.

[Scavenge Reaction Step S22]

Subsequently, as the vacuum gauge 309 detects attainment of a predetermined pressure, the control unit 311 controls the mechanism 308 to close the lid 307 of the crucible 304. Also, it starts heating of the crucible 304. In order to accelerate the scavenge reaction sufficiently, at the temperature band whereat the reaction is accelerated, the rate of heating the raw material may be lowered or, alternatively, a suitable temperature may be held for a long time.

[Scavenge Reaction Product Removing Step S23]

As the scavenge reaction progresses sufficiently and the attainment of a predetermined pressure is detected by the vacuum gauge 309, the control unit 311 control the mechanism 308 to open the lid 307 of the crucible 304 again. Then, heating is continued so that the raw material is fused completely. Again, the state in which scavenge reaction product or residual scavenger gas decreases and the vacuum level is stabilized, is waited for. What is aimed at here is to minimize evaporation of fluoride raw material and also to remove scavenge reaction product and residual scavenger outwardly of the crucible 304.

[Fusing and Solidifying Step S24]

As attainment of a predetermined pressure is detected by the vacuum gauge 309, the control unit 311 controls the mechanism 308 to close the lid 307 of the crucible 304 again. The fused fluoride is gradually cooled to be solidified. During gradual cooling, if the crucible 304 is pulled down, removal of impurities is improved significantly. Since the purpose of this process is to remove impurities to enlarge the bulk density, the fluoride obtained by this process may be a crystal including a particle phase. Therefore, a precise temperature control is not necessary. Of the crystal thus obtained, the top portion, that is, the portion having been crystallized last with respect to time, is removed. Since many impurities are collected in this portion, the removing operation described above effectively removes impurities that may adversely affect the characteristic.

[Monocrystal Growing Step S13]

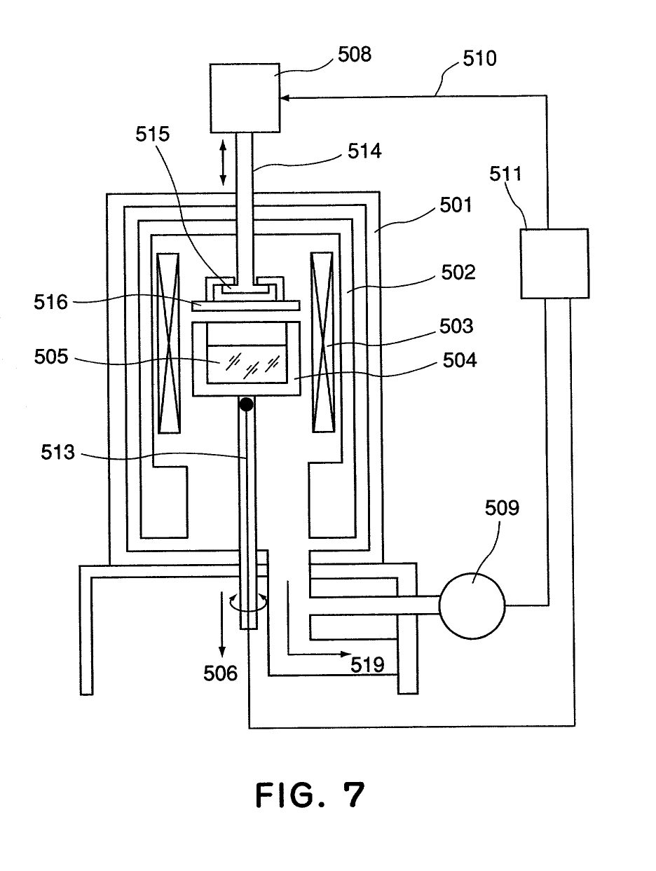

The refined crystal is used as a secondary raw material, and monocrystal of calcium fluoride is grown in a crystal growing furnace shown in FIG. 7. As regards the growing method, a suitable method may be chosen in accordance with the size of crystal or the purpose of use. For example, Bridgman method may be used to gradually pull down the crucible and cool it, by which monocrystal can be grown. Also in the monocrystal growth process, a scavenger is added to the raw material, but the amount of scavenger addition should be not less than 0.002 mol % of the raw material and not greater than 2 mol %. The reason for that the added amount is less than that in the refining process (Step S11) is that the secondary raw material used in this crystal growth process is a block-like crystal, so that the moisture amount adhered to the raw material is small as compared with the powder raw material used in the refining process. Similarly to the refining process, the fluoride to be used as a scavenger may desirably be zinc fluoride, manganese fluoride, lead fluoride, bismuth fluoride, sodium fluoride, lithium fluoride and the like. The function of scavenge reaction (impurity removing reaction through the scavenger) is similar to that in the refining process, and description thereof is omitted here.

The fluoride raw material in which the scavenger is added and mixed is put into a crucible of a crystal growth furnace shown in FIG. 7. In FIG. 7, denoted at 501 is a chamber for a crystal growing furnace, and it is connected to a vacuum exhaust system 512. Denoted at 502 is a heat insulating material, and denoted at 503 is a heater. Denoted at 504 is a crucible which functions as a room for accommodating the raw material. Denoted at 505 is the fluoride raw material. The element 506 is connected to a mechanism for moving the crucible upwardly and downwardly, and for rotating it about a vertical axis. The crucible is provided with a lid 516. Also, there is a mechanism 508 for moving the lid upwardly and downwardly at the top of the refining furnace. A lid opening and closing shaft (vertical portion) 514 is attached to it. At the bottom end of the lid opening/closing shaft (vertical portion), there is a horizontal portion 515. In the state in which the lid 516 is caught by this horizontal portion and thus it is suspended thereby, the whole opening/closing shaft is moved upwardly or downwardly by which the lid can be opened or closed. Therefore, the state in which the crucible lid is closed corresponds to a state in which the lid rides on the crucible without being suspended or a state in which the lid is pressed against the crucible. Also, the state in which the lid 516 is open, the lid is being suspended and lifted above the crucible. FIG. 7 shows a state in which the lid is open.

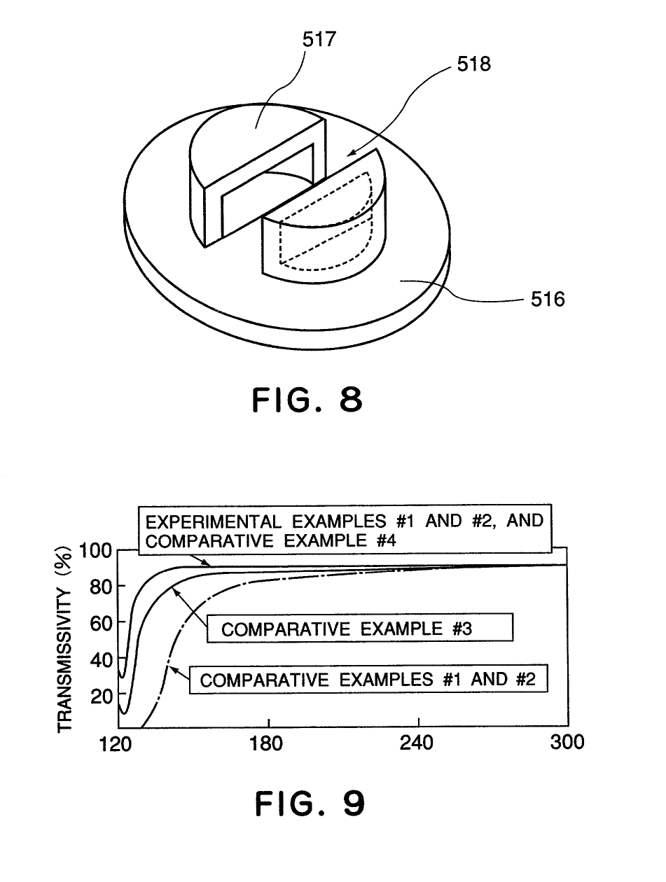

FIG. 8 shows the lid as it is seen obliquely from the above. Provided at the top of the lid is a suspending portion 517. In order to open the lid which is closed, initially, the horizontal portion 515 of the lid opening/closing shaft is inserted into a notch 518 and, after that, the crucible is rotated by 90 deg. so that the horizontal portion 515 of the lid opening/closing shaft is caught by the notch 518. Thereafter, the shaft is moved upwardly, by which the lid 516 is opened.

In order to close the lid being open, the lid opening/closing shaft 514 is moved downwardly so that the lid rides on the crucible. The shaft may be moved downwardly more so that the horizontal portion 515 of the shaft presses the lid against the crucible. As a feature of the present invention, in a crystal growing step S34 based on crucible pulling down (to be described later), the lid 516 is kept closed to prevent evaporation loss of fluoride raw material 505. Here, in order to allow that the crucible is pulled down through a relatively long distance while the lid is held closed, the following procedure may be taken.

As described hereinbefore, the lid opening/closing shaft 514 is moved downwardly so that the rid 516 rides on the crucible. Subsequently, the crucible is rotated by 90 deg. while the horizontal portion 515 of the shaft is not caught by the lid suspending portion 517. After this, the shaft is moved upwardly so that the horizontal portion 515 of the shaft disengages from the lid. By this operation, the lid 516 and the lid opening/closing shaft 514 are placed separate from each other. Thus, by pulling the crucible downwardly thereafter, the crucible can be pulled down through a relatively long distance with the lid held opened.

Denoted at 509 is a vacuum gauge for measuring the vacuum level inside the chamber. The measured vacuum level is signaled to a control unit 511. On the basis of the measurement result, the control unit 511 controls the lid moving mechanism 508 for opening and closing the lid of the crucible, through a signal line 510. The temperature of the crucible 504 is measured by means of a thermocouple 513, and the result is transmitted to the control unit 511.

[Dehydrating Step S31]

In this embodiment, initially, the control unit 511 controls the mechanism 508 so as to open the lid 516 of the crucible 504. Subsequently, the control unit 511 controls the vacuum exhaust system 512 to start gas exhaust. After the vacuum gauge 509 detects that a predetermined vacuum level is reached, the heater 503 is energized to heat the crucible 504. Since the moisture attracted to the fluoride raw material or the crucible 504 is removed by dehydration, from about 100-300° C., the rate of heating up to 300° C. or less may be made slower or, alternatively, an appropriate temperature between 100-300° C. may be held for a long time period. In this process, the stage whereat the dehydration has progressed largely is monitored by the vacuum gauge 509. The vacuum gauge 509 monitors whether the vacuum level is stable or not.

[Scavenge Reaction Step S32]

Subsequently, as the vacuum gauge 509 detects attainment of a predetermined pressure, the control unit 511 controls the mechanism 508 to close the lid 516 of the crucible 504. Also, it starts heating of the crucible 504. In order to accelerate the scavenge reaction sufficiently, at the temperature band whereat the reaction is accelerated, the rate of heating the raw material may be lowered or, alternatively, a suitable temperature may be held for a long time.

[Scavenge Reaction Product Removing Step S33]

As the scavenge reaction progresses sufficiently and the attainment of a predetermined pressure is detected by the vacuum gauge 509, the control unit 511 controls the mechanism 508 to open the lid 516 of the crucible 504 again. Then, heating is continued so that the raw material is fused completely. Again, the state in which scavenge reaction product or residual scavenger gas decreases and the vacuum level is stabilized, is waited for. What is aimed at here is to minimize evaporation of fluoride raw material and also to remove scavenge reaction product and residual scavenger outwardly of the crucible 504.

[Fusing and Crystal Growing Step S34]

As attainment of a predetermined pressure is detected by the vacuum gauge 509, the control unit 511 controls the mechanism 508 to close the lid 516 of the crucible 504 again. To this end, as described hereinbefore, the lid opening/closing shaft 514 is moved downwardly so that the lid 516 rides on the crucible. Then, in the state in which the horizontal portion 515 of the shaft 514 is not caught by the lid suspending portion 517, the crucible is rotated by 90 deg. After this, the shaft is moved upwardly to withdraw the horizontal portion 515 from the lid. By this operation, the lid 516 and the shaft 514 are placed separate from each other. Thus, by pulling the crucible downwardly thereafter, the crucible can be pulled down through a relatively long distance with the lid held opened. The pull-down speed (descending speed) of the crucible may be set, for example, in a range of 0.1-5 mm/H.

[Annealing Step S14]

Subsequently, the fluoride monocrystal having been grown as described is heat-processed in an annealing furnace (not shown), whereby birefringence is reduced.

[Shape Forming Step S15]

Thereafter, shape forming process is made by cutting, polishing or any other method, to obtain a shape required for an optical component (or optical element). The optical element may be, for example, a lens, a diffraction grating, an optical film, and a composite of them, that is, for example, one of a lens, a multiple lens, a lens array, a lenticular lens, a fly's eye lens, an aspherical lens, a diffraction grating, a binary optics element, and a composite of them. In addition to a single element of lens or the like, the optical element may be a photosensor for focus control, for example. If necessary, an antireflection film may be provided on the surface of an optical component made of fluoride crystal. As regards the antireflection film, magnesium fluoride, aluminum oxide, and tantalum oxide are suitably usable. The film can be formed by vapor deposition through resistance heating, electron beam deposition, or sputtering, for example. In the polishing process for obtaining the shape required for the optical component (for example, convex lens, concave lens, disk-like shape, or plate-like shape), because of small transition density inside the CaF2 crystal, a decrease of local surface precision is very small, such that high-precision processing is attainable.

In accordance with the present embodiment, the vacuum level of the furnace ambience is monitored, and the timing of opening/closing the lid of the crucible is determined in accordance with the result of monitoring. As a result, the lid can be opened and closed in accordance with the progress state of the producing processes, such as the state of dehydration, for example.

Further, in accordance with this embodiment, by opening and closing the lid of the crucible at respective stages before the fusion and solidification of the fluoride raw material in the refining procedure, harmful moisture or harmful scavenge reactant adhered to the raw material or to the furnace can be removed outwardly of the crucible. On the other hand, evaporation and resultant decrease of the fluoride crystal component can be prevented.

Further, in accordance with this embodiment, by opening and closing the lid of the crucible at respective stages after the fluoride raw material is fused and until the monocrystal is grown by crucible pull-down, harmful moisture or harmful scavenge reactant adhered to the raw material or to the furnace can be removed outwardly of the crucible. Particularly, since the lid of the crucible can be demounted from the lid opening/closing mechanism, the crucible can be pulled down through a relatively long distance while the lid is held closed. Thus, evaporation and resultant decrease of the crystal component during the crystal growth can be prevented.

As a result of this, there is provided a method of refining fluoride for production of fluoride crystal, by which, even if short-wavelength and high-power light such as excimer lasers is irradiated repeatedly and for a long term, the transmissivity characteristic is not easily deteriorated.

Further, there is provided a method by which excessive evaporation of fluoride raw material whose unit price is expensive is suppressed, by which the production cost can be lowered, and by which emission of industrial wastes can be decreased.

Even if the amount of moisture adhered to the fluoride raw material or the furnace changes with seasons or due to differences in material or in production lot, a stable dehydrated state can be accomplished, such that the quality product rate for refined product or final crystal can be improved significantly.

Although in the embodiment described above the exhaust of the inside gas of the crucible is performed by opening/closing the lid of the crucible, the exhaust mechanism is not limited to it.

Now, the present invention will be explained in greater detail, in conjunction with some specific examples.

### EXAMPLE 1

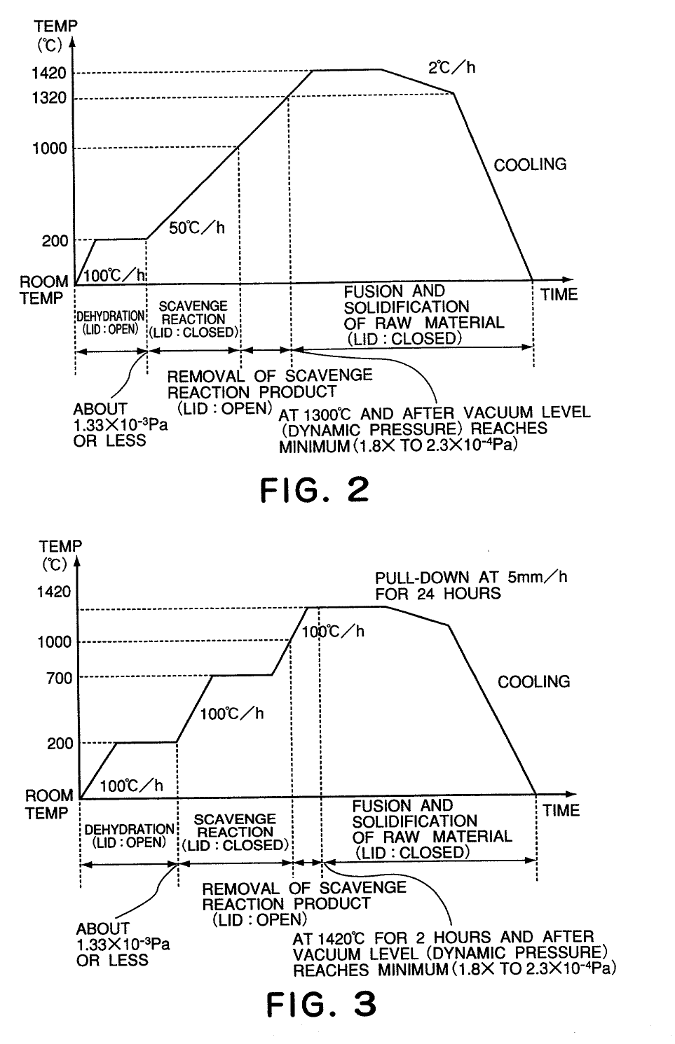

FIG. 2 shows data in relation to the refining step S12 performed in Example 1, and it illustrates the temperature, time, and the opened/closed state of the lid as well as the vacuum level as the opening/closing is switched.

(Raw Material Makeup Step S11)

To a high-purity synthetic CaF2 powder raw material of 1 Kg, zinc fluoride as a scavenger was added by 0.08 mol % (10.5 g), and they were mixed sufficiently.

(Refining Step S12)

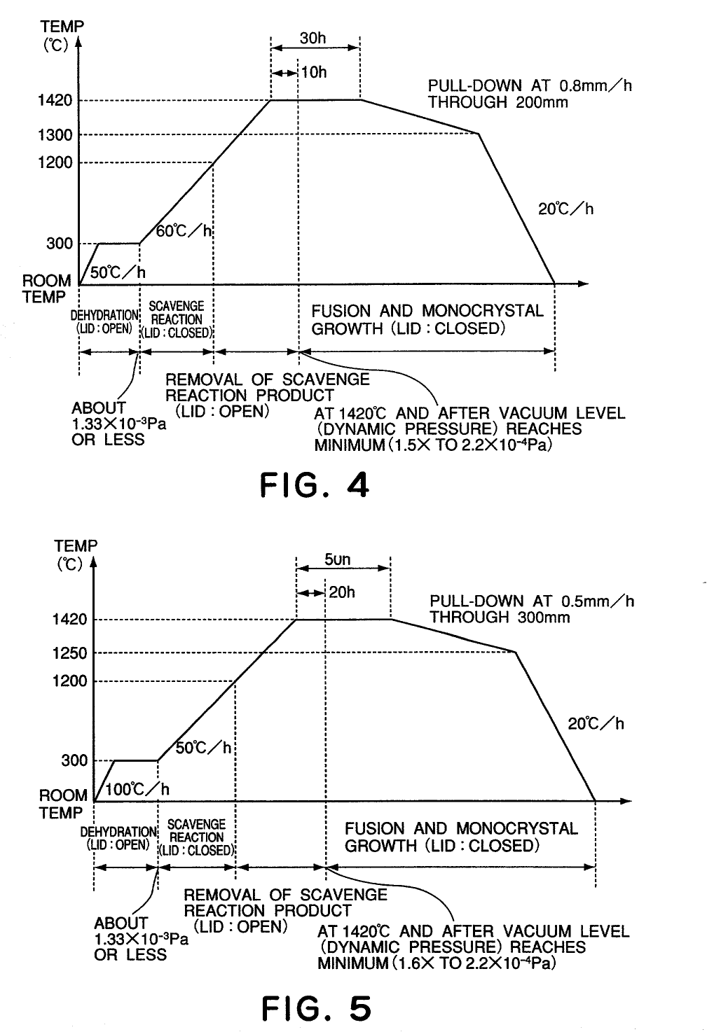

The fluoride raw material in which the scavenger was added and mixed was put into a refining furnace shown in FIG. 4.

(Dehydrating Step S21)

First, the lid of the crucible was held opened. Subsequently, vacuum exhaust was started. After the vacuum level reached 1.33×10⁻³ Pa or less, the heater was energized, and the heating of the crucible was started. The vacuum exhaust was continued until the refining step S12 was completed. As regards the heating rate, it was 100° C./h in the range from the room temperature to 200° C., and a temperature 200° C. was held for 24 hours. As regards changes in vacuum level (dynamic pressure), with the lapse of time from start of holding 200° C., initially it increased and, after that, it decreased gradually. After 20 hours or more elapsed from start of holding 200° C., it was substantially stabilized at about 1.33×10⁻³ Pa or less.

(Scavenge Reaction Step S22)

Subsequently, the lid of the crucible was closed. Again, the crucible was heated at a heating rate of 50° C./h. The reason for that the heating rate was slower than 100° C. was to assure that the impurity removal reaction through the scavenger was executed sufficiently. It has been found that, where zinc fluoride is used as a scavenger and added to calcium fluoride raw material, the scavenge reaction progresses in a temperature range of about 400-1300° C. Thus, the heating rate may be slowed within this range, or an appropriate temperature may be held for a long time, as required.

(Scavenge Reaction Product Removing Step S23)

When 1000° C. was attained, the pressure inside the furnace was about 5×10⁻⁴ Pa. Then, the lid of the crucible was opened again, and heating was continued at the same heating rate until a temperature (1420° C.) by which the raw material was fused was reached. Changes in vacuum level were observed. Also, the time whereat the vacuum level was stabilized was observed. What is aimed at there was to minimize evaporation of fluoride crystal component and to remove scavenge reaction product and residual scavenger outwardly of the crucible. Changes in the vacuum level from the opening of the lid at 1000° C. to the heating up to 1420° C. were as follows. After the lid was opened at 1000° C., the vacuum level (dynamic pressure) increased with the heating. It reached a maximum about 1100° C., and after that, it decreased a small. After about 1300° C. or more was exceeded, the level increased again gradually. Namely, in the structure of Example 1, the vacuum level was minimum at about 1300° C. (about 1.8 to2.3×10⁻⁴ Pa, for example, 2.0×10⁻⁴ Pa). This means that, beyond 1300° C., evaporation of the fluoride crystal component becomes gradually intense.

(Fusing and Solidifying Step S24)

After the minimum vacuum level at 1300° C. was confirmed, the lid of the crucible was closed at 1320° C. After that, heating was continued at the heating rate of 50° C./h, until 1420° C. was reached. Then, the material was held at 1420° C. for 10 hours and, after the material was fused sufficiently, the fused fluoride was gradually cooled at 2° C./h till 1300° C., whereby it was solidified. After that, it was cooled in the furnace to the room temperature. Although the removal of impurities is improved if during the gradual cooling the crucible is pulled down, it was not pulled down in Example 1. Since the purpose of this process is to remove impurities to enlarge the bulk density, the fluoride obtained by this process may be a crystal including a particle phase. Therefore, a precise temperature control is not necessary.

Of the crystal thus obtained, particularly the top portion, that is, the portion being crystallized last with respect to time, was removed. Since many impurities are collected in such portion, the removing operation described above effectively removes impurities that may adversely affect the characteristic.

The thus obtained calcium fluoride crystal (refined product) was cut and polished, and a disk of a thickness 10 mm was obtained. The transmission spectrum in the vacuum ultraviolet region was measured. FIG. 9 shows the results. The transmission spectrum in this case is based on the result which contains the reflection at two surfaces, and it differs from pure internal transmissivity. FIG. 9 also shows other examples and comparative examples to be described later. As seen from the drawing, there is no large absorption in the vacuum ultraviolet transmission spectrum in the refined product of Example 1.

In Example 1, the weight of the refined product with respect to the fluoride raw material of 10 Kg was about 0.9 Kg. The yield to the raw material in that case was 95%. Table 1 shows the yield of raw material at the stage where the refining was finished. Table 1 also shows the results of other examples and comparative examples to be described later.

(Monocrystal Growing Step S13)

By using the thus refined crystal as a raw material, monocrystal was grown. Bridgman method was used as the growing method. The crucible was pulled down at a descending speed of 2.0 mm per hour and it was cooled, whereby monocrystal was grown.

(Annealing Step S14)

Subsequently, the thus grown fluoride monocrystal was heat processed in an annealing furnace to reduce birefringence. The calcium fluoride monocrystal thus obtained was cut and polished, and a disk of a thickness 10 mm was obtained. Then, irradiation test with F2 excimer laser (157 nm) was performed to it. Specifically, a laser of an output 30 mJ/cm² was irradiated by 1×10³ pulses. Table 1 shows the internal transmissivity before and after the laser pulse irradiation. As seen from this table, the internal transmissivity of the monocrystal of Example 1 before the irradiation was 99.6% and that after the irradiation was 99.5%. Thus, it has a performance being durable for long term use. In the laser irradiation test conducted, a good internal transmissivity is not less than 99.5% (before irradiation) and not less than 99.4% (after irradiation).

(Shape Forming Step S15)

Thereafter, shape forming process may be made by cutting, polishing or any other method, to obtain a shape required for an optical component. If necessary, an antireflection film may be provided on the surface of an optical component made of fluoride crystal. Where lenses thus obtainable are combined, an optical system having a good durability to high energy laser such as excimer laser, particularly, ArF excimer laser or F2 excimer laser, can be provided. Also, by combining such optical system with a stage system for moving a substrate (workpiece to be exposed), an exposure apparatus can be provided.

### EXAMPLE 2

FIG. 3 shows data in relation to the refining step S12 performed in Example 2, and it illustrates the temperature, time, and the opened/closed state of the lid as well as the vacuum level as the opening/closing is switched.

Since the structure of the refining furnace is similar to that in Example 1, detailed description thereof will be omitted. The size of the crucible, for example, is adjusted appropriately in accordance with the size of crystal to be produced.

(Raw Material Makeup Step S11)

To a high-purity synthetic CaF2 powder raw material of 30 Kg, zinc fluoride as a scavenger was added by 0.13 mol % (50 g), and they were mixed sufficiently.

(Refining Step S12)

The fluoride raw material in which the scavenger was added and mixed was put into a refining furnace shown in FIG. 4.

(Dehydrating Step S21)

First, the lid of the crucible was held opened. Subsequently, vacuum exhaust was started. After the vacuum level reached 1.33×10⁻³ Pa or less, the heater was energized, and the heating of the crucible was started. The heating was made at 100° C./h from the room temperature to 200° C., and a temperature 200° C. was held

Also in Example 2, changes in vacuum level were relied upon as an index for completion of holding 20020 C. Changes in vacuum level (dynamic pressure) were qualitatively the same as Example 1. With the lapse of time from start of holding 200° C., initially the vacuum level increased and, after that, it decreased gradually. After 28 hours or more elapsed from start of holding 200° C., it was substantially stabilized at about 1.33×10−3Pa or less.

(Scavenge Reaction Step S22)

To reserve a margin, the lid of the crucible was closed after 32 hours from start of holding 200 ° C. Again, the crucible was heated at a heating rate of 100° C./h. As the crucible temperature reached 700° C., it was held at 700° C. for 10 hours, for impurity removing reaction through scavenger.

(Scavenge Reaction Product Removing Step S23)

After holding 700° C., the crucible was heated again at a heating rate 100° C./h up to 1000° C., and then the lid was opened. The pressure inside the furnace just before the lid was opened, was about 5×10⁻⁴ Pa. While the lid was kept opened, heating was continued until a temperature (1420° C.) by which the raw material was fused was reached, and changes in vacuum level were observed. In Example 2, the vacuum level became minimum after elapse of 2 hours from attainment of 1420° C. (about 1.8 to 2.3×10⁻⁴ Pa, for example, 2.0×10⁻⁴ Pa). After that, the vacuum level (dynamic pressure) increased. Namely, it has been found that, by holding the material at 1420° C. for 2 hours, scavenge reaction products can be removed outwardly of the crucible.

(Fusing and Solidifying Step S24)

In consideration of the above, in Example 2, after holding at 1420° C. for 2 hours, the lid of the crucible was closed. Then, the material was held at the same temperature for more 10 hours (total 12 hours at 1420° C.). After the raw material was fused sufficiently, the fused fluoride was pulled down at a pull-down speed of 5 mm/h, for 24 hours, and then it was solidified. The pull-down distance was 120 mm. At the same time, by using the mechanism 308, the lid 307 of the crucible was moved downwardly at a descending speed 5 mm/h. Therefore, during the pull-down of the crucible, the lid was held closed. After that, the fluoride was cooled in the furnace to the room temperature. Of the crystal thus obtained, particularly the top portion, that is, the portion being crystallized last with respect to time, was removed, by about 2 mm. Since many impurities are collected in such portion, the removing operation described above effectively removes impurities that may adversely affect the characteristic.

The thus obtained calcium fluoride crystal (refined product) was cut and polished, and a disk of a thickness 10 mm was obtained. The transmission spectrum in the vacuum ultraviolet region was measured. The result is that there is no particular absorption in the transmission spectrum in vacuum ultraviolet region (FIG. 9). Also, the yield of raw material was 96% (Table 1).

(Monocrystal Growing Step S13)

By using the thus refined crystal as a raw material, monocrystal was grown. Bridgman method was used as the growing method. The crucible was pulled down at a descending speed of 2.0 mm per hour and it was cooled, whereby monocrystal was grown.

(Annealing Step S14)

Subsequently, the thus grown fluoride monocrystal was heat processed in an annealing furnace to reduce birefringence. The calcium fluoride monocrystal thus obtained was cut and polished, and a disk of a thickness 10 mm was obtained. Then, irradiation test with F2 excimer laser (157 nm) was performed to it. Specifically, a laser of an output 30mJ/cm² was irradiated by 1×10³ pulses. The internal transmissivity was 99.8% (before irradiation) and 99.8% (after irradiation), and no change found (Table 1). Thus, it had a performance being durable for long term use.

### EXAMPLES 3

Like Example 1, to a high-purity synthetic CaF2 powder raw material of 1 Kg, zinc fluoride as a scavenger was added by 0.08 mol % (10.5 g), and they were mixed sufficiently. Then, the refining step S12 was carried out under the same conditions as Example 1. Namely, at the dehydrating step S21, vacuum exhaust was performed while keeping the lid of the crucible open (from room temperature to 200° C.). At the scavenge reaction step S22, while holding the crucible lid closed, the material was heated from 200° C. to 1000° C. At the scavenge reaction product removing step S23, it was heated to 1000 to 1300° C., while keeping the lid opened. At the fusing and solidifying step S24, the material was fused while the lid was closed again, and it was held at a temperature 1300-1420° C. Thereafter, it was gradually cooled while the lid is held closed, whereby it was solidified.

(Monocrystal Growing Step S13)

Substances adhered to the surface of the thus refined crystal were scraped off, and the resultant was used as a secondary material. By using a crystal growing furnace shown in FIG. 7, monocrystal was grown. Bridgman method was used as the growing method. The crucible was pulled down at a descending speed of 0.8 mm per hour and it was cooled, whereby monocrystal was grown. The processes will be described in greater detail below, in order. Initially, to a secondary raw material of 9.5 Kg, zinc fluoride as a scavenger was added by 0.008 mol % (1.00 g). The fluoride raw material in which the scavenger was added was put into a crystal growing furnace shown in FIG. 7.

(Dehydrating Step S31)

First, the lid of the crucible was held opened. Subsequently, vacuum exhaust was started. After the vacuum level reached 1.33×10⁻³ Pa or less, the heater was energized, and the heating of the crucible was started. The vacuum exhaust was continued until the monocrystal growing step S13 was completed. As regards the heating rate, it was 50° C./h in the range from the room temperature to 300° C., and a temperature 300° C. was held for 24 hours. As regards changes in vacuum level (dynamic pressure), with the lapse of time from start of holding 300° C., initially it increased and, after that, it decreased gradually. After 15 hours or more elapsed from start of holding 300° C., it was substantially stabilized at about 1.33×10⁻³ Pa or less.

(Scavenge Reaction Step S22)

Subsequently, the lid of the crucible was closed, and the crucible was heated at a heating rate of 60° C./h. It has been found that, where zinc fluoride is used as a scavenger and added to calcium fluoride raw material, the scavenge reaction progresses in a temperature range of about 400-1300° C. Thus, the heating rate may be slowed within this range, or an appropriate temperature may be held for a long time, as required.

(Scavenge Reaction Product Removing Step S33)

As 1200° C. was reached, the pressure of ambience inside the furnace was about 6×10⁻⁴ Pa. Then, the lid of the crucible was opened again, and heating was continued at the same heating rate until a temperature (1420° C.) by which the raw material was fused was attained. Changes in vacuum level were observed. Also, the time whereat the vacuum level was stabilized was observed. What is aimed at there was to minimize evaporation of fluoride crystal component and to remove scavenge reaction product and residual scavenger outwardly of the crucible. Changes in the vacuum level from the opening of the lid at 1200° C. to the heating up to 1420° C. were as follows. After the lid was opened at 1200° C., the vacuum level (dynamic pressure) increased with the heating. It reached a maximum about 1250° C., and after that, it decreased a small. The vacuum level showed a minimum after about 10 hours elapsed from attainment of 1420° C. (about 1.5 to 2.2×10⁻⁴ Pa, for example, 1.8×10⁻⁴ Pa). After that, the vacuum level (dynamic pressure) increased. Thus, it has been found that, by holding the material at 1420 ° C. for 10 hours, scavenge reaction products or the like can be removed outwardly of the crucible.

(Fusing and Crystal Growing Step S34)

In consideration of the above, in Example 3, after holding at 1420° C. for 10 hours, the lid of the crucible was closed. Then, the material was held at the same temperature for more 20 hours (total 30 hours at 1420° C.), so that the raw material was fused sufficiently. Then, the lid opening/closing shaft is disengaged from the lid. To this end, as described hereinbefore, in the state in which the horizontal portion 515 of the lid opening/closing shaft does not bear the suspending portion of the lid, the crucible is rotated by 90 deg so that the horizontal portion 515 can be withdrawn from the notch 518. After this, the shaft 514 is moved upwardly to withdraw the horizontal portion 515 from the lid. By this operation, the lid 516 and the shaft 514 are placed separate from each other. Thus, by pulling the crucible downwardly thereafter, the crucible can be pulled down through a relatively long distance with the lid held opened. The pull-down speed (descending speed) of the crucible was 0.8 mm/H, and the pull-down length was 200 mm. The time required for the pull-down was 250 hours. After the pull-down, it was cooled to the room temperature, at a temperature descending rate of 20° C./H.

In Example 3, for a calcium fluoride secondary raw material (crystal produced by refining) of 9.5 Kg, monocrystal of 9.0 Kg weight was obtained (yield 95%).

(Annealing Step S14)

Subsequently, the thus grown fluoride monocrystal was heat processed in an annealing furnace to reduce birefringence. The calcium fluoride monocrystal thus obtained was cut and polished, and a disk of a thickness 10 mm was obtained. Then, irradiation test with F2 excimer laser (157 nm) was performed to it. Specifically, a laser of an output 30 mJ/cm² was irradiated by 1×10³ pulses. Table 1 shows the internal transmissivity before and after the laser pulse irradiation. As seen from this table, the internal transmissivity of the monocrystal of Example 3 before the irradiation was 99.9% and that after the irradiation was 99.8%. Thus, it has a performance being durable for long term use. In the laser irradiation test conducted, a good internal transmissivity is not less than 99.5% (before irradiation) and not less than 99.4% (after irradiation).

(Shape Forming Step S15)

Thereafter, a shape forming process may be made by cutting, polishing or any other method, to obtain a shape required for an optical component. If necessary, an antireflection film may be provided on the surface of an optical component made of fluoride crystal. Where lenses thus obtainable are combined, an optical system having a good durability to high energy laser such as excimer laser, particularly, ArF excimer laser or F2 excimer laser, can be provided. Also, by combining such optical system with a stage system for moving a substrate (workpiece to be exposed) an exposure apparatus can be provided.

### EXAMPLE 4

Like Example 1, to a high-purity synthetic CaF2 powder raw material of 10 Kg, zinc fluoride as a scavenger was added by 0.08 mol % (10.5 g), and they were mixed sufficiently. Then, the refining step S12 was carried out under the same conditions as Example 1. In Example 4, the refining process was made four times, and four refined crystals were produced.

(Monocrystal Growing Step S13)

Substances adhered to the surface of the thus refined crystals were scraped off, and the resultants were used as a secondary material (total 38.3 Kg). By using a crystal growing furnace shown in FIG. 7, monocrystal was grown. Bridgman method was used as the growing method. The crucible was pulled down at a descending speed of 0.5 mm per hour and it was cooled, whereby monocrystal was grown. The processes will be described in greater detail below, in order. Initially, to a secondary raw material of 38.2 Kg, zinc fluoride as a scavenger was added by 0.04 mol % (20.2 g). The fluoride raw material in which the scavenger was added was put into a crystal growing furnace shown in FIG. 7.

(Dehydrating Step S31)

Initially, the lid of the crucible was held opened. Subsequently, vacuum exhaust was started. After the vacuum level reached 1.33×10⁻³ Pa or less, the heater was energized, and the heating of the crucible was started. The vacuum exhaust was continued until the monocrystal growing step S13 was completed. As regards the heating rate, it was 100° C./h in the range from the room temperature to 300° C., and a temperature 300° C. was held for 24 hours. As regards changes in vacuum level (dynamic pressure), with the lapse of time from start of holding 300° C., initially it increased and, after that, it decreased gradually. After 20 hours or more elapsed from start of holding 300° C., it was substantially stabilized at about 1.33×10⁻³ Pa or less.

(Scavenge Reaction Step S32)

Subsequently, the lid of the crucible was closed, and the crucible was heated at a heating rate of 50° C./h. It has been found that, where zinc fluoride is used as a scavenger and added to calcium fluoride raw material, the scavenge reaction progresses in a temperature range of about 400-1300° C. Thus, the heating rate may be slowed within this range, or an appropriate temperature may be held for a long time, as required.

(Scavenge Reaction Product Removing Step S33)

As 1200° C. was reached, the pressure of ambience inside the furnace was about 9×10⁻⁴ Pa. Then, the lid of the crucible was opened again, and heating was continued at the same heating rate until a temperature (1420° C.) by which the raw material was fused was attained. Changes in vacuum level were observed. Also, the time whereat the vacuum level was stabilized was observed. What is aimed at there was to minimize evaporation of fluoride crystal component and to remove scavenge reaction product and residual scavenger outwardly of the crucible. Changes in the vacuum level from the opening of the lid at 1200° C. to the heating up to 1420° C. were as follows. After the lid was opened at 1200° C., the vacuum level (dynamic pressure) increased largely with the heating. It reached a maximum about 1250° C., and after that, it decreased. The vacuum level showed a minimum after about 20 hours elapsed from attainment of 1420° C. (about 1.6 to 2.2×10⁻⁴ Pa, for example, 2.0×10⁻⁴ Pa). After that, the vacuum level (dynamic pressure) increased. This increase is due to evaporation of fluoride crystal component. Thus, it has been found that, by holding the material at 142° C. for 20 hours, scavenge reaction products or the like can be removed outwardly of the crucible.

(Fusing and Crystal Growing Step S34)

In consideration of the above, in Example 4, after holding at 1420° C. for 20 hours, the lid 516 of the crucible was closed. Then, the material was held at the same temperature for more 30 hours (total 50 hours at 1420° C.), so that the raw material was fused sufficiently. Then, the lid opening/closing shaft 514 was disengaged from the lid 516 (details of separating operation are omitted). With this operation, the crucible can be pulled down through a relatively long distance with the lid held opened. The pull-down speed (descending speed) of the crucible was 0.5 mm/H, and the pull-down length was 300 mm. The time required for the pull-down was 600 hours. After the pull-down, it was cooled to the room temperature, at a temperature descending rate of 20° C./H.

In Example 4, for a calcium fluoride secondary raw material (crystal produced by refining) of 38.2 Kg, monocrystal of 35.9 Kg weight was obtained (yield 94%).

(Annealing Step S14)

Subsequently, the thus grown fluoride monocrystal was heat processed in an annealing furnace to reduce birefringence. The calcium fluoride monocrystal thus obtained was cut and polished, and a disk of a thickness 10 mm was obtained. Then, irradiation test with F2 excimer laser (157 nm) was performed to it. Specifically, a laser of an output 30 mJ/cm² was irradiated by 1×10³ pulses. Table 1 shows the internal transmissivity before and after the laser pulse irradiation. As seen from this table, the internal transmissivity of the monocrystal of Example 4 before the irradiation was 99.8% and that after the irradiation was 99.7%. Thus, it has a performance being durable for long term use. In the laser irradiation test conducted, a good internal transmissivity is not less than 99.5% (before irradiation) and not less than 99.4% (after irradiation).

(Shape Forming Step S15)

Thereafter, a shape forming process may be made by cutting, polishing or any other method, to obtain a shape required for an optical component. If necessary, an antireflection film may be provided on the surface of an optical component made of fluoride crystal. Where lenses thus obtainable are combined, an optical system having a good durability to high energy laser such as excimer laser, particularly, ArF excimer laser or F2 excimer laser, can be provided. Also, by combining such optical system with a stage system for moving a substrate (workpiece to be exposed), an exposure apparatus can be provided.

### Comparative Examples

Next, some comparative examples will be described to explain the effectiveness of the present invention. In these comparative examples, basically, crystal was produced through a similar procedure including raw material makeup step S11, monocrystal growing step S13, annealing step S14, and shape forming step S15.

First, Comparative Examples 1-5 will be described. Among these examples, the procedure except the refining step S12 was performed in accordance with Example 1 and. Therefore, the refining step will be explained mainly.

### Comparative Example 1

Like Example 1, to a high-purity synthetic CaF2 powder raw material of 10 Kg, zinc fluoride as a scavenger was added by 0.08 mol % (10.5 g), and they were mixed sufficiently. The refining step S12 in Comparative Example 1 was performed under the same condition as Example 1, except for the dehydrating step S21. Namely, at the dehydrating step S12 vacuum exhaust was made with the lid of crucible kept closed (from room temperature to 200° C.). Example 1 differs in that removal of adhered moisture was made with the lid of crucible kept opened. At the scavenge reaction step S22, the lid is held closed, and the material was heated from 200° C. to 1000° C. At the scavenge reaction product removing step S23 the lid is held opened, and the material was heated to 1000-1300° C. At the fusing and solidifying step S24 the material was fused while the lid was closed again. A temperature of 1300-1420° C. was maintained. Thereafter, it was gradually cooled while the lid was held closed, whereby the material was solidified.

The calcium fluoride crystal (refined product) thus obtained was cut and polished, whereby a disk of a thickness 10 mm was obtained. Transmissive spectrum in the vacuum ultraviolet region was measured. The result is that, as shown in FIG. 9, there is absorption at the shorter wavelength side. By using the thus produced crystal as a raw material, monocrystal was grown under similar conditions as of Example 1, and then an annealing process was performed. The internal transmissivity of the obtained monocrystal with respect to F2 excimer laser (157 nm) was only 78.0% (before irradiation) and 74.0% (after irradiation). Thus, both the transmissivity performance and laser durability performance were inferior (Table 1).

### Comparative Example 2

Like Example 1, to a high-purity synthetic CaF2 powder raw material of 10 Kg, zinc fluoride as a scavenger was added by 0.08 mol % (10.5 g), and they were mixed sufficiently.

The subsequent refining step S12 in Comparative Example 2 was performed under the same condition as Example 1, except for the scavenge reaction step S22. Namely, at the dehydrating step S21 vacuum exhaust was made with the lid of crucible kept opened, and room temperature to 200° C. was held. At the scavenge reaction product removing step S23 the lid is held opened, and the material was heated to 1000-1300° C. At the fusing and solidifying step S24 the material was fused while the lid was closed again, and it was heated to 1300-1420° C. Thereafter, it was gradually cooled while the lid was held closed, whereby the material was solidified.

The calcium fluoride crystal (refined product) thus obtained was cut and polished, whereby a disk of a thickness 10 mm was obtained. Transmissive spectrum in the vacuum ultraviolet region was measured. The result is that there is absorption at the shorter wavelength side (FIG. 9). By using the thus produced crystal as a raw material, monocrystal was grown under similar conditions as of Example 1, and then an annealing process was performed. The internal transmissivity of the obtained monocrystal with respect to F2 excimer laser (157 nm) was only 79.5% (before irradiation) and 76.2% (after irradiation). The internal transmissivity was inferior (Table 1).

### Comparative Example 3

Like Example 1, to a high-purity synthetic CaF2 powder raw material of 10 Kg, zinc fluoride as a scavenger was added by 0.08 mol % (10.5 g), and they were mixed sufficiently.

The subsequent refining step S12 in Comparative Example 3 was performed under the same condition as Example 1, except for the scavenge reaction product removing step S23. Namely, at the dehydrating step S21 vacuum exhaust was made with the lid of crucible kept opened, and room temperature to 200° C. was held. At the scavenge reaction step S22, the lid is held closed, and the material was heated to 200-1000° C. At the scavenge reaction product removing step S23 the lid is held closed, and the material was heated to 1000-1300° C. In Example 1, as compared, this process was performed with the lid held opened. At the fusing and solidifying step S24 the material was fused while the lid was closed, and it was heated to 1300-1420° C. Thereafter, it was gradually cooled while the lid was held closed, whereby the material was solidified.

The calcium fluoride crystal (refined product) thus obtained was cut and polished, whereby a disk of a thickness 10 mm was obtained. Transmissive spectrum in the vacuum ultraviolet region was measured. The result is that there is absorption at the shorter wavelength side (FIG. 9). By using the thus produced crystal as a raw material, monocrystal was grown under similar conditions as of Example 1, and then an annealing process was performed. The internal transmissivity of the obtained monocrystal with respect to F2 excimer laser (157 nm) was only 79.5% (before irradiation) and 76.2% (after irradiation). The internal transmissivity was inferior (Table 1).

### Comparative Example 4

Like Example 1, to a high-purity synthetic CaF2 powder raw material of 10 Kg, zinc fluoride as a scavenger was added by 0.08 mol % (10.5 g), and they were mixed sufficiently.

The subsequent refining step S12 in Comparative Example 4 was performed under the same condition as Example 1, except for the fusing and solidifying step S24. Namely, at the dehydrating step S21 the lid of crucible was opened, and the material was heated from room temperature to 200° C. At the scavenge reaction step S22, the lid is held closed, and the material was heated to 200-1000° C. At the scavenge reaction product removing step S23 the lid is held opened, and the material was heated to 1300-1420° C. Thereafter, it was gradually cooled while the lid was held opened, whereby the material was solidified.

The calcium fluoride crystal (refined product) thus obtained was cut and polished, whereby a disk of a thickness 10 mm was obtained. Transmissive spectrum in the vacuum ultraviolet region, before and after irradiation with gamma radiation, was measured. The condition for irradiating gamma radiation was the same as the embodiment.

In the crystal (refined product) obtained by the experiment of Comparative Example 4, there was no absorption in the vacuum ultraviolet region, like the crystal of Example 1, and it shows a good transmissivity characteristic (FIG. 9). Subsequently, monocrystal growth and annealing were performed to it, whereby monocrystal was obtained. Then, F2 excimer laser pulse was projected to it for a long term. But, a decrease of internal transmissivity was small, and it showed a performance being durable to long term use (Table 1). Since, however, in Comparative Example 4, the lid of the crucible was open during the fusing and solidifying step S24 in the refining procedure, evaporation of the fluoride raw material was very large. Therefore, the weight of refined product obtained from calcium fluoride raw material of 10 Kg was only about8.5 Kg (yield 85%). As compared therewith, in Example 1, a refined product of 9.5 Kg was obtained (yield 95%). In consideration of it, the method of Comparative Example 4 cannot be said as a preferable refining method, and the production cost is high (Table 1). Further, due to large evaporation of fluoride raw material, emission of industrial wastes is large.

### Comparative Example 5

Like Example 2, to a high-purity synthetic CaF2 powder raw material of 30 Kg, zinc fluoride as a scavenger was added by 0.13 mol % (50 g), and they were mixed sufficiently. The subsequent refining step in Comparative Example 5 was performed while the temperature, time, and the opened/closed state of the crucible lid were fixed as the same as those of Example 2, and several fluoride raw material refining experiments were repeated. The refining condition can be summarized as follows.

That is, at the dehydrating step S21 vacuum exhaust was performed while the lid of crucible was opened, and a pressure not greater than 1.33×10⁻³ Pa was attained. While continuing the vacuum exhaust with the lid held opened, the material was heated from room temperature to 200° C., at 100° C./h. At 200° C., it was held for 32 hours. At the scavenge reaction product removing step S23 the lid is held opened at 1000° C. While holding the lid opened, and the material was heated to 1420° C., at 100° C./h. It was held at 1420° C. for 2 hours. At the fusing and solidifying step S24 the lid is closed again, and the material was held at 1420° C. for more 10 hours, whereby it was fused sufficiently. Thereafter, the crucible was pull down at a speed 5 mm/h while holding the lid closed, for 24 hours, and the material was solidified. Then, it was cooled in the furnace to the room temperature.

The refining of fluoride raw material under this refining condition was tried eight times, from November to February, next year. Also, a little while later, it was tried eight times, from June to September. The calcium fluoride crystals (refined products) thus obtained were cut and polished, whereby disks of a thickness 10 mm were obtained. Then, transmission spectrums of these products in the ultraviolet region were measured. The results (not shown) were that, in seven refined products out of eight produced from November to February, next year, there was no particular absorption in the transmission spectrum in the vacuum ultraviolet region. A small absorption was found at the short wavelength side, only in one sample. On the other hand, as regards eight refined products from June to September, absorptions at the shorter wavelength side were found in five products.

As for those refined products (crystals) in which no absorption occurred in the short wavelength side in the vacuum ultraviolet region, a crystal growing step and an annealing step similar to those of Example 2 were preformed. As a result, crystals having a good transmissivity performance with respect to F2 excimer laser (157 nm) were obtained.

As described, in Comparative Example 5, fluoride raw material refining experiments were carried out while fixing the temperature, time and the opened/closed state of the crucible lid under the same conditions as of Example 2. The result is that, for the products from November to February, next year, the proportion of quality products is good (i.e. 7/8); whereas, for products from June to September, it was not good. This may be due to a large difference in humidity between winter and summer, and a large difference in moisture amount adhered to the fluoride raw material or refining furnace. Namely, in the above-described experiments, the condition for temperature and time at the dehydrating step S21 was fixed, and the subsequent steps (from scavenge reaction step) were carried out without checking the state of dehydration by observing the vacuum level. Because of it, where the humidity was high in summer, sufficient dehydration might not be accomplished, and the fluoride raw material being oxidized might be left.

Next, Comparative Examples 6-9 will be described. These examples are comparative experiments in relation to Example 3. Specifically, among various processes in Example 3, the order of opening and closing the crucible lid at steps S31-S34, constituting the monocrystal growing step S13, was reversed. Except it, the procedure was the same as Example 3.

### Comparative Example 6

Like Example 3, to a high-purity synthetic CaF2 powder raw material of 10 Kg, zinc fluoride as a scavenger was added by 0.08 mol % (10.5 g), and they are mixed sufficiently. After that, it was fused and solidified, and refined crystal was produced.

In the monocrystal growing step S13 of Comparative Example 6, vacuum exhaust at the dehydrating step S31 was carried out while the crucible lid held closed (from room temperature to 300° C.). Example 3 differs in that removal of adhered moisture was made with the crucible lid held opened. Except this, the procedure was the same as Example 3.

As regards the internal transmissivity of the thus produced calcium fluoride monocrystal (annealed product) with respect to F2 excimer laser (157 nm), it was only 85.0% (before laser irradiation) and 80.2% (after laser irradiation). Thus, both of transmissivity performance and laser durability performance were inferior (Table 1).

### Comparative Example 7

Like Example 3, to a high-purity synthetic CaF2 powder raw material of 10 Kg, zinc fluoride as a scavenger was added by 0.08 mol % (10.5 g), and they are mixed sufficiently. After that, it was fused and solidified, and refined crystal was produced.

In the monocrystal growing step S13 of Comparative Example 7, the material was heated at the scavenge reaction step S22 to 1000° C. to 1300° C., while the crucible lid held opened. Example 3 differs in that the crucible lid was held closed during this procedure. Except this, the procedure was the same as Example 3.

As regards the internal transmissivity of the thus produced calcium fluoride monocrystal (annealed product) with respect to F2 excimer laser (157 nm), it was only 76.0% (before laser irradiation) and 70.3% (after laser irradiation). Thus, both of transmissivity performance and laser durability performance were inferior (Table 1).

### Comparative Example 8

Like Example 3, to a high-purity synthetic CaF2 powder raw material of 10 Kg, zinc fluoride as a scavenger was added by 0.08 mol % (10.5 g), and they are mixed sufficiently. After that, it was fused and solidified, and refined crystal was produced.

In the monocrystal growing step S13 of Comparative Example 8, the material was heated at the scavenge reaction product removing step S23 to 1000° C. to 1300° C., while the crucible lid held closed. Example 3 differs in that the crucible lid is held opened during this procedure. Except this, the procedure was the same as Example 3.

As regards the internal transmissivity of the thus produced calcium fluoride monocrystal (annealed product) with respect to F2 excimer laser (157 nm), it was only 82.0% (before laser irradiation) and 79.6% (after laser irradiation). Thus, both of transmissivity performance and laser durability performance were inferior (Table 1).

### Comparative Example 9

Like Example 3, to a high-purity synthetic CaF2 powder raw material of 10 Kg, zinc fluoride as a scavenger was added by 0.08 mol % (10.5 g), and they are mixed sufficiently. After that, it was fused and solidified, and refined crystal was produced.

In the monocrystal growing step S13 of Comparative Example 9, the crucible was pulled down at the fusing and monocrystal growing step S34, while the crucible lid held opened. Example 3 differs in that the crucible lid is held closed during this procedure. Except this, the procedure was the same as Example 3.

As regards the internal transmissivity of the thus produced calcium fluoride monocrystal (annealed product) with respect to F2 excimer laser (157 nm), it was 99.9% (before laser irradiation) and 99.8% (after laser irradiation). Like the crystal of Example 3, there was no absorption in the vacuum ultraviolet region, and the transmissivity was good (Table 1). Since, however, in Comparative Example 9, the lid of the crucible was open during the crystal growth (step S34), evaporation of the fluoride raw material was very large. Therefore, the weight of produced monocrystal, obtained from the calcium fluoride secondary raw material (crystal obtained by refining) of 9.5 Kg, was only about 7.5 Kg (yield 79%). As compared therewith, in Example 1, a monocrystal of 9.0 Kg was obtained (yield 95%). In consideration of it, the method of Comparative Example 9 cannot be said as a preferable refining method, and the production cost is high (Table 1). Further, due to large evaporation of fluoride raw material, emission of industrial wastes is large.

TABLE 1

| | | INTERNAL TRANSMISSIVITY | | |
|---|---|---|---|---|
| | | (MONOCRYSTAL) | | |
| | | BEFORE LASER | AFTER LASER | |
| | YIELD | IRRADIATION | IRRADIATION | NOTE |
| EXAMPLE 1 | 95% (REFINED) | 99.6% | 99.5% | GOOD |
| EXAMPLE 2 | 96% (REFINED) | 99.8% | 99.8% | GOOD |
| EXAMPLE 3 | 95% | 99.9% | 99.8% | GOOD |
| | (MONOCRYSTAL) | | | |
| EXAMPLE 4 | 94% | 99.8% | 99.7% | GOOD |
| | (MONOCRYSTAL) | | | |
| COMPARATIVE | | 78.0% | 74.0% | BAD INTERNAL |
| EXAMPLE 1 | | | | TRANSMISSIVITY |
| COMPARATIVE | | 79.5% | 76.2% | BAD INTERNAL |
| EXAMPLE 2 | | | | TRANSMISSIVITY |
| COMPARATIVE | | 90.3% | 88.6% | BAD INTERNAL |
| EXAMPLE 3 | | | | TRANSHISSIVITY |
| COMPARATIVE | 85% (REFINED) | 99.5% | 99.4% | BAD YIELD |
| EXAMPLE 4 | | | | |
| COMPARATIVE | | | | QUALITY PRODUCT |
| EXAMPLE 5 | | | | RATE CHANGED |
| | | | | WITH SEASONS: |
| COMPARATIVE | | 85.9% | 80.2% | BAD INTERNAL |
| EXAMPLE 6 | | | | TRANSMISSIVITY |
| COMPARATIVE | | 76.0% | 70.3% | BAD INTERNAL |
| EXAMPLE 7 | | | | TRANSMISSIVITY |
| COMPARATIVE | | 82.0% | 79.6% | BAD INTERNAL |
| EXAMPLE 8 | | | | TRANSMISSIVITY |
| COMPARATIVE | 79% | 99.9% | 99.8% | BAD YIELD |
| EXAMPLE 9 | (MONOCRYSTAL) | | | |

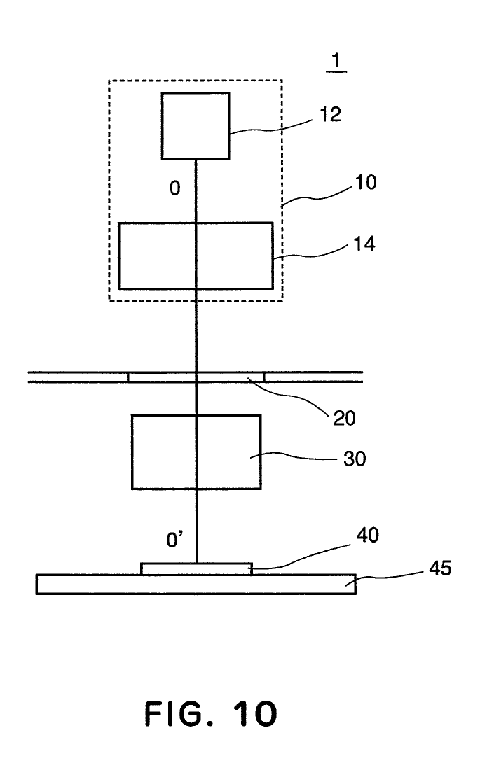

Referring now to FIG. 10, an exposure apparatus 1 according to an embodiment of the present invention will be described. Here, FIG. 10 is a schematic and sectional view of an exposure apparatus, as an example according to the present invention.

As shown in FIG. 10, the exposure apparatus 1 comprises an illumination system 10, a reticle 20, a projection optical system 30, a plate 40, and a stage 45. The exposure apparatus is a scan type projection exposure apparatus in which a circuit pattern formed on the reticle 20 is transferred to the plate 40 in accordance with a step-and-repeat method or a step-and-scan method.

The illumination system 10 serves to illuminate the reticle 20 having a transfer circuit pattern formed thereon, and it includes a light source unit 12 and an illumination optical system 14.

The light source unit 12 may comprise a laser, for example, as a light source. The laser may be ArF excimer laser having a wavelength of about 193 nm, KrF excimer laser having a wavelength of about 248 nm, or F2 excimer laser having a wavelength of about 157 nm, for example. The type of laser is not limited to excimer laser. For example, YAG laser may be used. Also, the number of lasers is not limited. Where a laser is used in the light source unit 12, a beam shaping optical system for transforming parallel light from the laser light source into a desired beam shape, as well as an incoherency transforming optical system for transforming coherent laser light into incoherent light, may desirably be used. However, the light source usable in the light source unit 12 is not limited to laser. One or plural lamps such as Hg lamp or xenon lamp may be used.

The illumination optical system 14 is an optical system for illuminating the mask 20. It includes a lens, a mirror, a light integrator, a stop and the like. For example, a condenser lens, a fly's eye lens, an aperture stop, a condenser lens, a slit, and an imaging optical system may be provided in this order. The illumination optical system 14 can be used with either axial light or abaxial light. The light integrator may comprise an integrator such as a fly's eye lens or combined two sets of cylindrical lens array (or lenticular lens) plates. Alternatively, it may be replaced by an optical rod or diffractive element. An optical element produced in accordance with the present invention can be used as optical elements such as lenses in this illumination optical system 14.

The reticle has formed thereon a circuit pattern (or image) to be transferred. The reticle is supported and moved by a reticle state, not shown. Diffraction light from the reticle 20 goes through the projection optical system 30, and it is projected on the plate 40. The plate 40 may be a workpiece such as a wafer or a liquid crystal substrate, and it is coated with a resist material. The reticle 20 and the plate 40 are placed in an optically conjugate relation with each other. Where the exposure apparatus is scan type projection exposure apparatus, the mask 20 and the plate 40 are scanningly moved, by which the pattern of the mask 20 is transferred to the plate 40. If the exposure apparatus is a step-and-repeat type exposure apparatus (stepper), the exposure process is performed while the mask 20 and the plate 40 are held fixed.

The projection optical system 30 may be an optical system consisting lens elements only, an optical system (catadioptric system) having lens elements and at least one concave mirror, an optical system having lens elements and at least one diffractive optical element such as kinoform, for example, or an all-mirror type optical system, for example. If correction of chromatic aberration is necessary, lens elements made of glass materials having different dispersions (Abbe's numbers), or alternatively, a diffractive optical element may be provided so as to produce dispersion in opposite direction to lens elements. An optical element produced in accordance with the present invention can be used as optical elements such as lenses in the projection optical system 30.

The plate is coated with a photoresist. The photoresist coating process includes a pre-process, an adherence enhancing agent coating process, a photoresist coating process, and a pre-baking process. The pre-process includes washing, drying and the like. The adherence enhancing agent coating process is a surface improving process (i.e., hydrophobing treatment based on coating with a surface active agent) for improving the adherence between the photoresist and the ground material. In this process, an organic film such as HMDS (Hexamethyl-disilazane), for example, is applied by coating or vapor treatment. The pre-baking is a baking treatment, but it is gentle as compared with that to be done after the development. It is to remove any solvent.

The stage 45 supports the plate 40. Since any structure known in the art can be used for the stage 45, detailed description of the structure and function of it will be omitted. For example, linear motors may be used in the state 45 to move the plate 40 in X and Y directions. The reticle 20 and the plate 40 may be scanningly moved in synchronism with each other, for example. The position of the stage 45 and the position of a reticle stage (not shown) may be monitored by use of laser interferometers, for example, and these stages may be driven at a constant speed ratio. The stage 45 may be provided, for example, on a stage base which is supported by the floor, or the like, through dampers. The reticle stage and the projection optical system 40 may be provided on a barrel base (not shown) which is supported by a base frame, mounted on the floor, for example, through dampers or the like.

In the exposure process, light emitted from the light source unit 12 illuminates the reticle 20, in Koehler illumination, for example, through the illumination optical system 14. The light passing through the reticle 20 and reflecting the mask pattern is imaged on the plate 40 by the projection optical system 30. The illumination optical system 14 and the projection optical system 30 used in the exposure apparatus may include optical elements produced in accordance with the present invention, so that each can transmit ultraviolet light, deep ultraviolet light or vacuum ultraviolet light at a high transmissivity. Additionally, because of good refractive index homogeneity and small birefringence, devices such as semiconductor devices, LCD devices, image pickup devices (e.g., CCD) or thin magnetic heads, for example, can be produced at a higher resolution and a higher throughput, and economically.

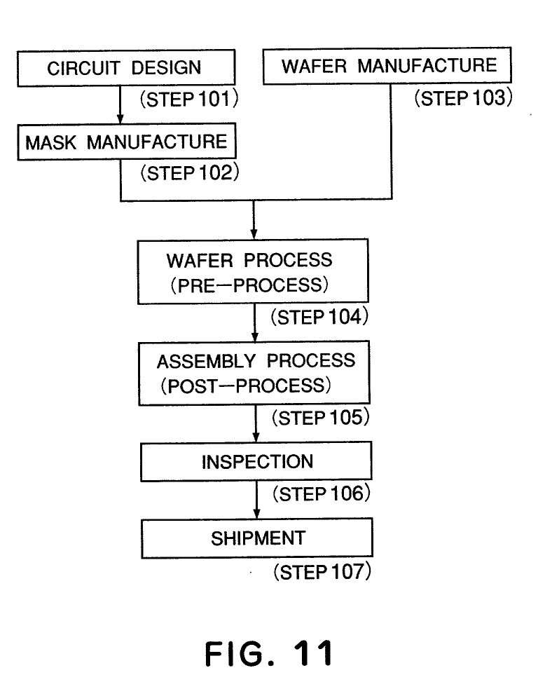

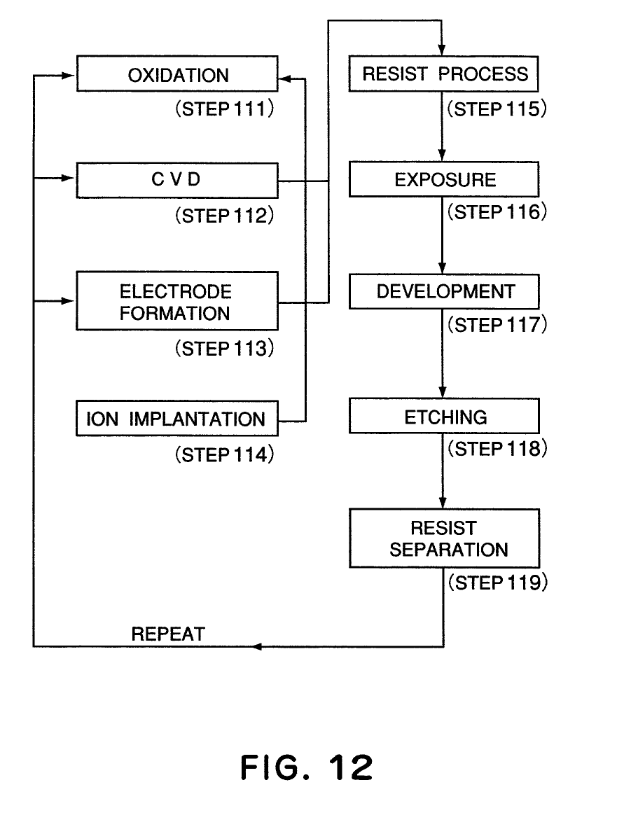

Next, referring to FIGS. 11 and 12, an embodiment of a device manufacturing method which uses an exposure apparatus described above, will be explained.

FIG. 11 is a flow chart for explaining the procedure of manufacturing various microdevices such as semiconductor chips (e.g., ICs or LSIs), liquid crystal panels, CCDs, thin film magnetic heads or micro-machines, for example. Step 101 is a design process for designing a circuit of a semiconductor device. Step 102 is a process for making a mask on the basis of the circuit pattern design. Step 103 is a process for preparing a wafer by using a material such as silicon. Step 104 is a wafer process which is called a pre-process wherein, by using the thus prepared mask and wafer, a circuit is formed on the wafer in practice, in accordance with lithography. Step 105 subsequent to this is an assembling step which is called a post-process wherein the wafer having been processed at step 104 is formed into semiconductor chips. This step includes an assembling (dicing and bonding) process and a packaging (chip sealing) process. Step 106 is an inspection step wherein an operation check, a durability check an so on, for the semiconductor devices produced by step 105, are carried out. With these processes, semiconductor devices are produced, and they are shipped (step 107).

FIG. 12 is a flow chart for explaining details of the wafer process at step 104. Step 111 is an oxidation process for oxidizing the surface of a wafer. Step 112 is a CVD process for forming an insulating film on the wafer surface. Step 113 is an electrode forming process for forming electrodes upon the wafer by vapor deposition. Step 114 is an ion implanting process for implanting ions to the wafer. Step 115 is a resist process for applying a resist (photosensitive material) to the wafer. Step 116 is an exposure process for printing, by exposure, the circuit pattern of the mask on the wafer through the exposure apparatus described above. Step 117 is a developing process for developing the exposed wafer. Step 118 is an etching process for removing portions other than the developed resist image. Step 119 is a resist separation process for separating the resist material remaining on the wafer after being subjected to the etching process. By repeating these processes, circuit patterns are superposedly formed on the wafer.

With the method of the present invention, devices of higher quality can be manufactured.

Although some embodiments and examples of the present invention have been described above, the present invention is not limited to the disclosed form. Various modifications are possible within the scope of the invention.

In accordance with a crystal producing method and apparatus according to the present invention, both breathing and closedness of the crucible are assured and, also, the breathing can be adjusted at a desired level. This is very effective to produce a fluoride crystal having superior optical performance, including transmissivity. Further, an optical element to be produced from such calcium fluoride crystal can be incorporated into an optical system of an exposure apparatus, for example, for manufacturing high quality devices based on good resolution and good throughput exposure process.

While the invention has been described with reference to the structures disclosed herein, it is not confined to the details set forth and this application is intended to cover such modifications or changes as may come within the purposes of the improvements or the scope of the following claims.

What is claimed is:

1. A method of producing fluoride crystal, comprising the steps of:
dehydrating a raw material of fluoride by heating a crucible being adapted to accommodate a raw material of fluoride therein and having an exhaust mechanism for exhausting an inside gas of the crucible; and
exhausting, in said dehydrating step, an inside gas of the crucible by use of the exhaust mechanism.

2. A method according to claim 1, wherein the crucible is further adapted to accommodate a scavenger therein, and wherein said method further comprises a step of causing reaction of the scavenger to remove impurities contained in the fluoride raw material, and a step of sealingly closing the crucible without performing the gas exhaust from the crucible by the exhaust mechanism, in said reaction step.

3. A method according to claim 1, wherein the crucible is further adapted to accommodate a scavenger therein, and wherein said method further comprises a step of removing a product produced as a result of reaction of the scavenger, and a step of exhausting an inside gas of the crucible by use of the exhaust mechanism in said removing step.

4. A method according to claim 1, further comprising a step of fusing, solidifying or crystal-growing the fluoride raw material, and a step of sealingly closing the crucible without performing the gas exhaust from the crucible by the exhaust mechanism, in said fusing, solidifying or crystal-growing step.

5. A method according to claim 1, wherein the exhaust mechanism includes an openable/closable lid provided at a top of the crucible.

6. A method according to claim 5, wherein the lid is demountable from an opening/closing mechanism for the lid.

7. A method of producing fluoride crystal, comprising the steps of:
detecting a vacuum level of a process chamber for accommodating therein a crucible being adapted to accommodate a raw material of fluoride therein and having an exhaust mechanism for exhausting an inside gas of the crucible; and
controlling the gas exhaust through the exhaust mechanism, on the basis of the vacuum level detected.

8. A method according to claim 7, wherein the exhaust mechanism includes an openable/closable lid provided at a top of the crucible.

9. A method according to claim 8, wherein the lid is demountable from an opening/closing mechanism for the lid.

10. A crystal producing apparatus, comprising:
a process chamber for producing fluoride crystal;
a pressure detecting unit for detecting a pressure of said process chamber;
a crucible accommodated in said process chamber and being adapted to accommodate a raw material of fluoride therein, said crucible having an exhaust mechanism for exhausting an inside gas of said crucible; and
a control unit for controlling the gas exhaust through said exhaust mechanism, on the basis of the pressure of said process chamber detected by said pressure detecting unit.

11. An apparatus according to claim 10, wherein said exhaust mechanism includes an openable/closable lid provided at a top of said crucible.

12. An apparatus according to claim 11, wherein said lid is demountable from an opening/closing mechanism for said lid.

13. An optical element produced by use of a crystal of fluoride produced by a manufacturing apparatus as recited in claim 10.

14. An optical element according to claim 13, wherein said optical element is one of a lens, a diffraction grating, an optical film and a composite of them.

15. An exposure apparatus in which one of ultraviolet light, deep ultraviolet light and vacuum ultraviolet light is used as exposure light, and wherein the exposure light is projected on a workpiece through an optical system including an optical element as recited in claim 14 to expose the workpiece with the exposure light.

16. A device manufacturing method, comprising the steps of:
exposing a workpiece by use of an exposure apparatus as recited in claim 15; and
performing a predetermined process to the exposed workpiece.

17. A device as manufactured from a workpiece exposed by use of an exposure apparatus as recited in claim 15.
